(19) United States
(12) Patent Application Publication
(10) Pub. No.: US 2006/0203459 A1
(43) Pub. Date: Sep. 14, 2006

(54) Method of mounting a substrate to a motherboard

(76) Inventors: Thomas O. Morgan, Hillsboro, OR (US); Dudi Amir, Portland, OR (US); Damion Searls, Hillsboro, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/078,930

(22) Filed: Mar. 11, 2005

(51) Int. Cl. H05K 7/06

(52) U.S. Cl. 361/768; 361/803; 361/783; 361/779

(57) ABSTRACT

In one embodiment a method is provided. A method comprising forming a plurality of electromechanical formations to electromechanical couple a first printed circuit board to a second printed circuit board, wherein each electromechanical formation is of a first size; and forming at least one anchoring formation to anchor the first printed circuit board to the second printed circuit board, each anchoring formation being formed at a selected anchor point, and being of a second size which is greater than the first size.

### FIELD OF THE INVENTION

Embodiments of the invention relate to surface mount technology (SMT) in which a first printed circuit board is electromechanically coupled to a second printed circuit board.

### BACKGROUND

In surface mount technology (SMT) a first printed circuit board (PCB) may be electromechanically coupled to a second printed circuit board (PCB) through electromechanical formations in the form of solder joints formed between an underside of the first PCB, and an upper side of the second PCB. The first PCB may be a substrate board which is likewise electromechanically coupled to a semiconductor die comprising an integrated circuit. The second PCB may be a motherboard for mounting the substrate board and semiconductor die combination. The semiconductor die and substrate board combination is usually referred to as a semiconductor package.

Each electromechanical formation forms an input/output (I/O) to the integrated circuit. As I/O counts increase, more electromechanical formations are required, and thus a size of each electromechanical formation has to be decreased in order to accommodate the electromechanical formations within the same area. Decreasing the size of the electromechanical formations makes them more fragile with the result that stress in the for of deformation along the peripheral edges of the first PCB due to coefficient of thermal expansion (CTE) mismatches between the first and second PCBs, leads to failure of the electromechanical formations formed along the peripheral edges.

### BRIEF DESCRIPTION OF THE DRAWINGS

FIG. 1 illustrates a flip-chip assembly process, in accordance with prior art;

FIG. 2 shows a carrier board with a plated area in accordance with one embodiment of the invention;

FIG. 3 shows an anchoring formation/joint formed between a carrier board and a substrate board, in accordance with one embodiment of the invention;

FIG. 4 illustrates a stencil used to print solder material over the plated areas of a carrier board, in accordance with one embodiment of the invention;

FIG. 5 shows the shapes of different plated areas of a carrier board, in accordance with one embodiment of the invention;

FIG. 6 illustrates a wraparound solder joint formed between a carrier board and a substrate board, in accordance with one embodiment of the invention;

FIG. 7 illustrates a modified solder printing technique, in accordance with one embodiment of the invention;

FIGS. 8 and 9 illustrate different embodiments of anchoring formations formed between a carrier board and a substrate board, in accordance with one embodiments of the invention;

FIG. 10 illustrates a de-paneling technique, in accordance with one embodiment of the invention; and

FIG. 11 shows the components of a system, in accordance with one embodiment of the invention.

### DETAILED DESCRIPTION

In the following description, for purposes of explanation, numerous specific details are set forth in order to provide a thorough understanding of the invention. It will be apparent, however, to one skilled in the art that the invention can be practiced without these specific details. In other instances, structures and devices are shown in block diagram form in order to avoid obscuring the invention.

Reference in this specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments.

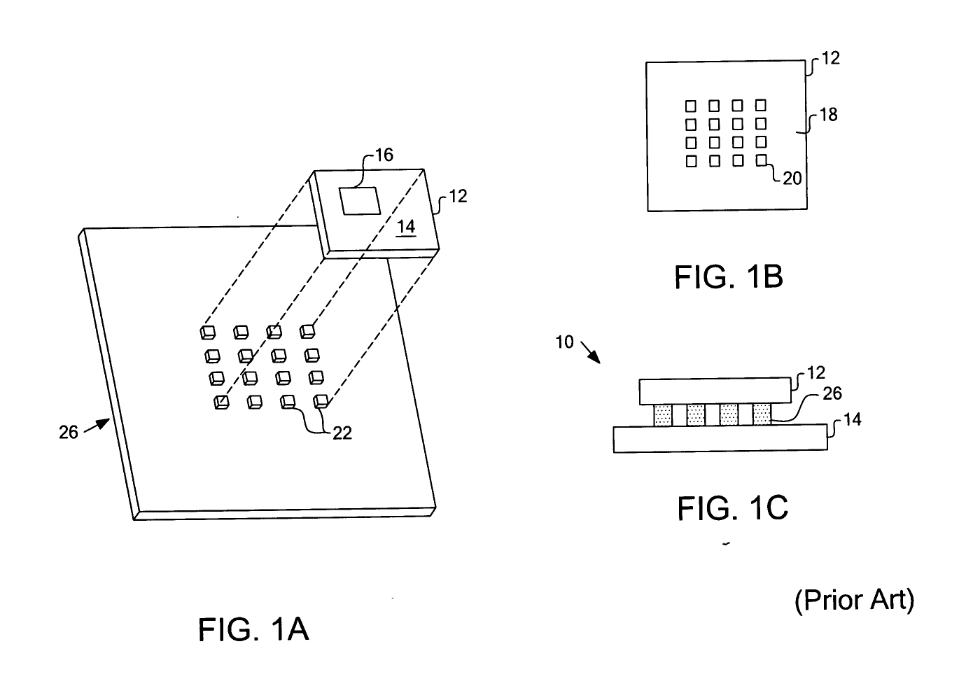

FIG. 1A of the drawings illustrates the flip-chip assembly process of the prior art. Referring to FIG. 1A, processing component 10 includes a first printed circuit board in the form of substrate board 12 which is mounted to a second printed circuit board in the form of a carrier or motherboard 26. The substrate board 12 has a semiconductor die 16 mounted on an operatively upper side 14 thereof, whereas an operatively under side 18 of the substrate board 12 includes solder bumps 20 (as can be seen in FIG. 1B of the drawings) formed thereon. During the flip-chip assembly process, the solder bumps 20 are aligned with corresponding solder bumps 22 formed on an operatively upper side 24 of a second printed circuit board in the form of a carrier or motherboard 26. The components 12 and 26 are brought into contact and a reflow operation is performed to reflow the solder bumps 22 and 20 so that an electromechanical solder joint 27 is formed between the components (see FIG. 1C of the drawings).

In one embodiment of the present invention, the above-described flip-chip assembly process includes the formation of at least one of anchoring formation in addition to the solder joints 27. The purpose of the anchoring formation is to anchor the substrate 12 to the motherboard 26 thereby to at least reduce failure of the solder joints 27 due to relative movement between substrate 12 and the motherboard 26, for example, due to coefficient thermal of execution (CTE) mismatches between these components.

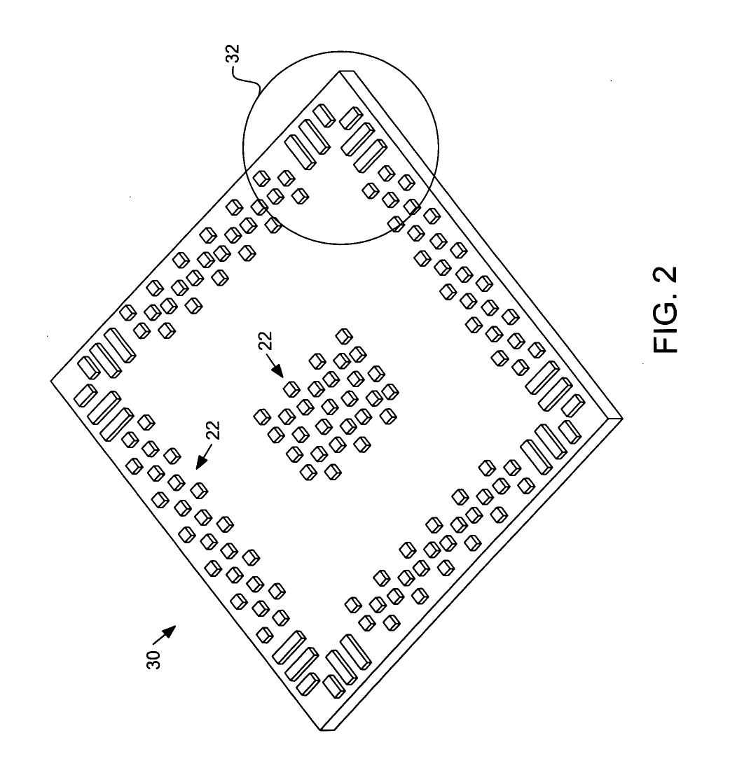

Accordingly, in one embodiment of the invention, a motherboard such as the motherboard 30 shown in FIG. 2 of the drawings is used. As before, the motherboard 30 includes a plurality of solder bumps 22. However, in addition to the solder bumps 22, the motherboard 30 also includes plated areas 32. The plated areas 32 are comprised of a solder-wettable material and are located at selected anchor points on the motherboard 30. In the example shown in FIG. 2 of the drawings, the anchor points are located at the four corners of the motherboard 30.

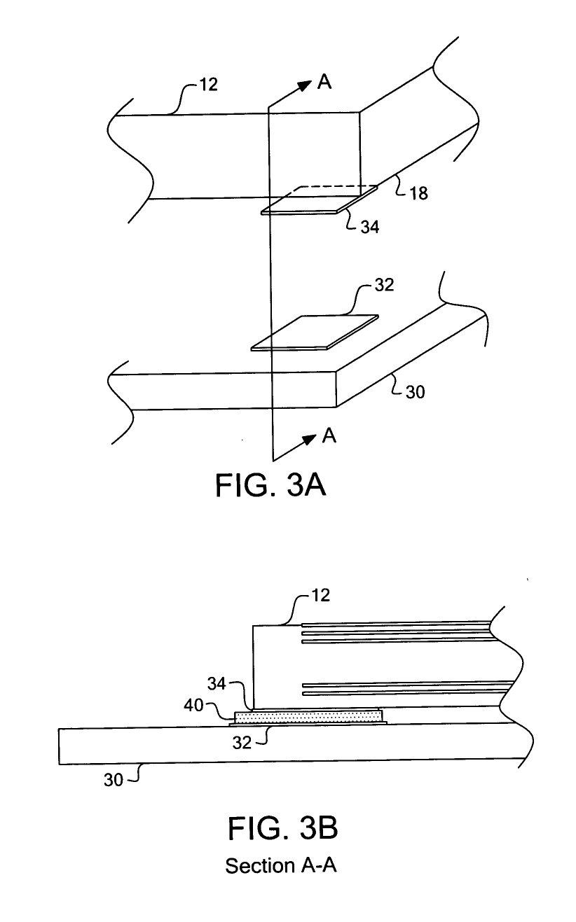

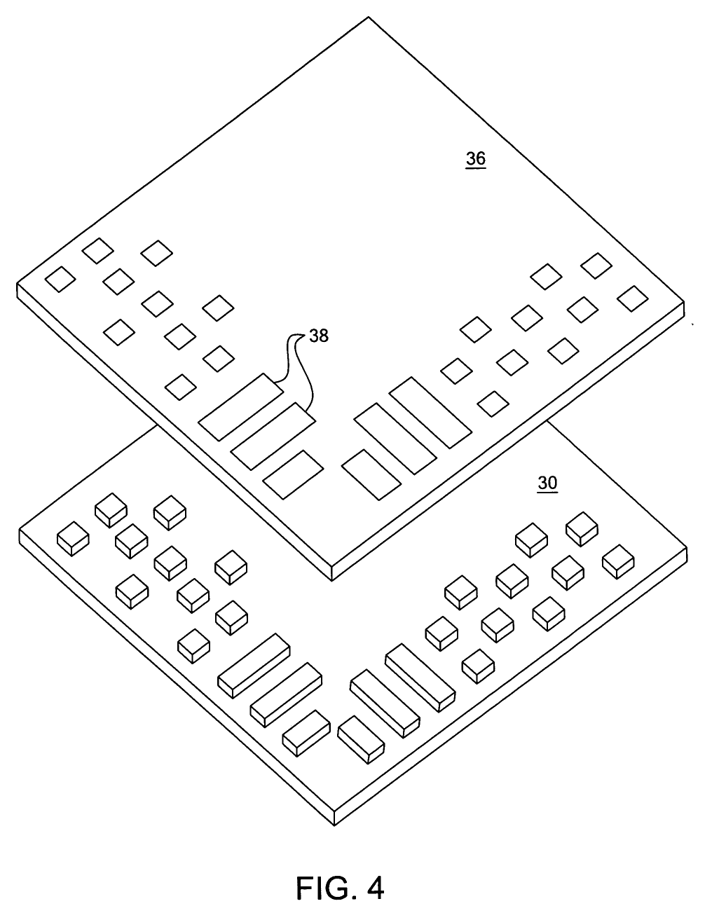

In accordance with the techniques disclosed herein, to be compatible with the motherboard 30, the substrate board 12 is modified so that the under side 18 thereof includes complementary plated areas (not shown) that match the complementary plated area 32 of the motherboard 30. For example, referring the FIG. 3 of the drawings, the substrate board 12 is shown to include a complementary plated area 34 formed on the under side 18. The plated area 34 is complementary to and matches the complementary plated area 32 of the motherboard 30. During the flip-chip assembly process, the complementary plated area 32 of the motherboard 30 is coated with a solder material. For example, a solder printing stencil 36 (see FIG. 4 of the drawings) may be placed over the motherboard 30 in order to deposit the solder material over the complementary plated area 32. As will the seen, the stencil 36 includes openings 38 which match the complementary plated area 32. Referring again to FIG. 3A of the drawings, during the flip-chip assembly process, the substrate board 12 is brought into contact with the motherboard 30 so that the deposited solder material (not shown) is sandwiched between the plated areas 34, 32 of the motherboard 30 and the substrate board 12, respectively. Thereafter, a solder reflow operation is performed in order to form an anchoring formation/joint 40 between each complementary plated area 34 of the substrate 12 and its corresponding plated area 32 of the motherboard 30. The anchoring formation/joint 40 is larger than the solder joint 27.

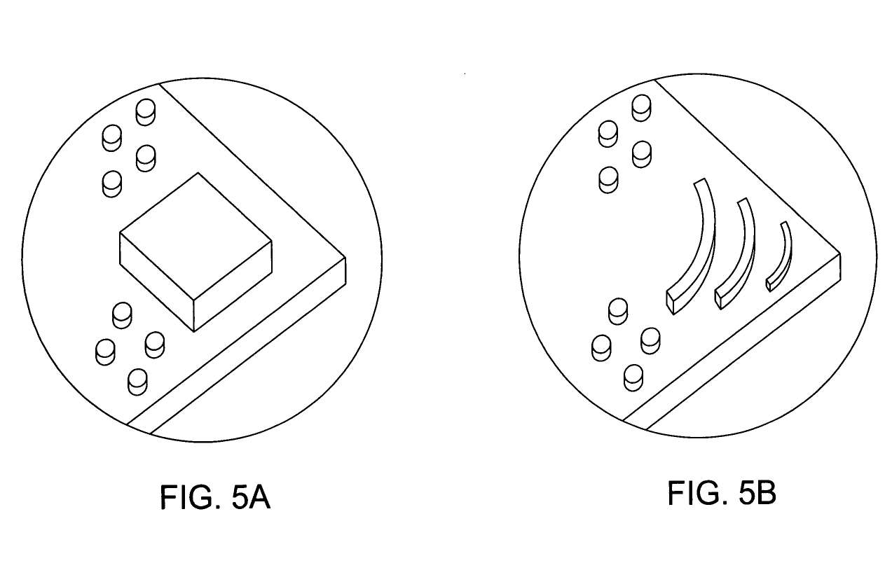

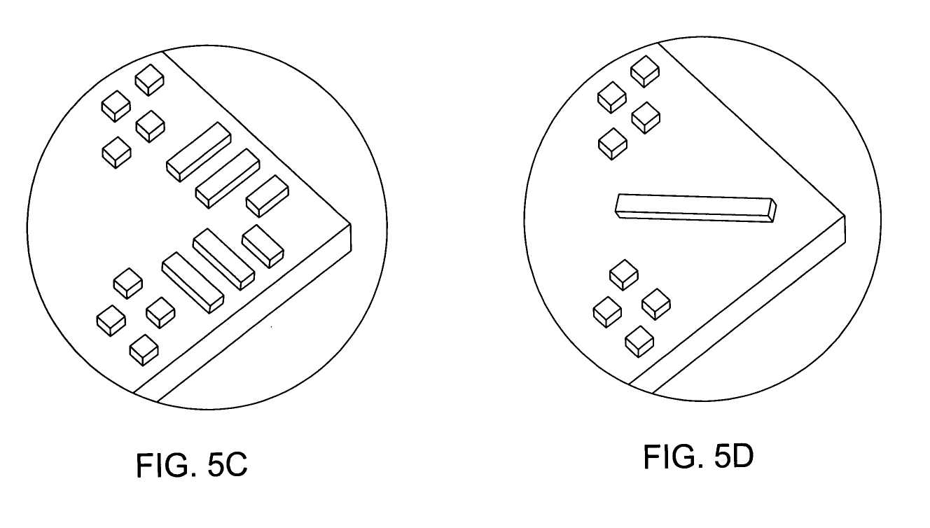

Various shapes and configurations are possible for the complementary plated areas 32 and 34. Referring to FIG. 5 of the drawings, a few of such configurations and shapes are illustrated. For example, the plated areas may be square (see FIG. 5A), the plated areas may have an arcuate shape (see FIG. 5B of the drawings), the plated areas may include a number of rectangular sub-areas (see FIG. 5C), or the plated areas may include a single rectangular area (see FIG. 5D) of the drawings.

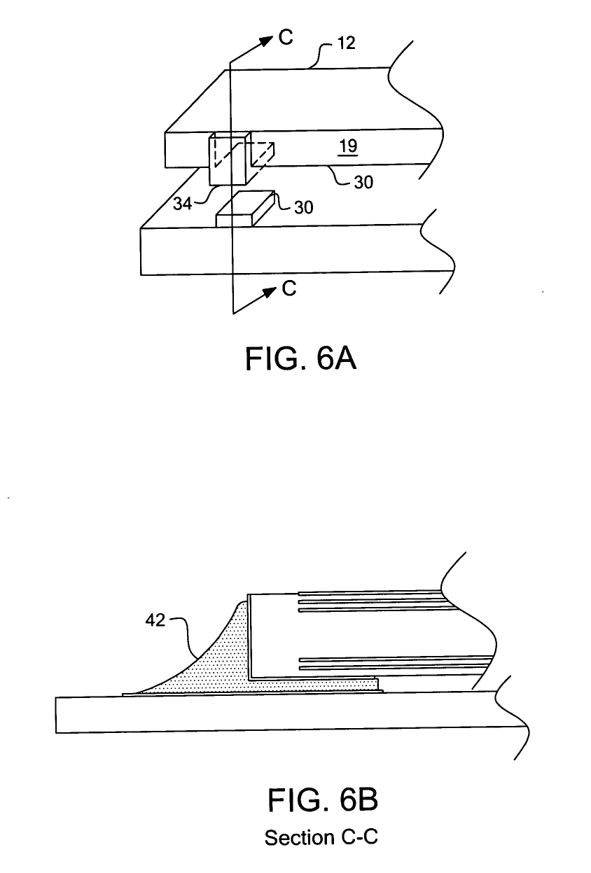

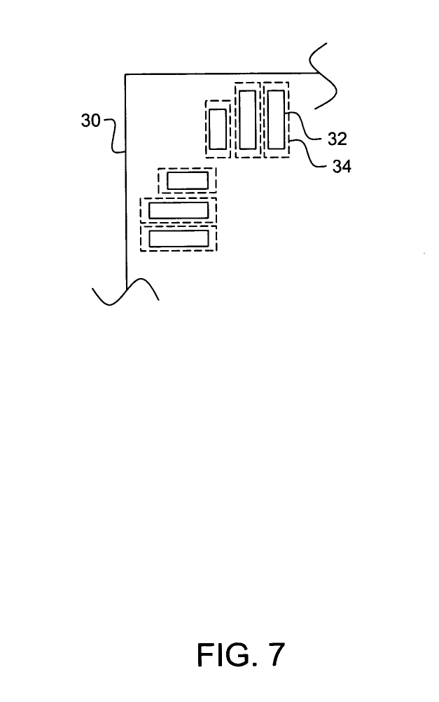

It will be appreciated, that the resultant anchoring formations/joints illustrated thus far have been restricted to a single plane. However, it is possible, in some embodiments, to form an anchoring formation/joint that is not limited to a single plane. One example of an anchoring formation/joint that is formed to anchor the substrate 12 to the motherboard 30, that is not limited to being in a single plane is illustrated in FIGS. 6A and 6B of the drawings. Referring the FIG. 6A, a motherboard 14 includes a rectangular-shaped plated area 32, and a substrate board 12 includes an L-shaped complementary plated area 34. The L-shaped complementary area 34 extends along the under side 18 of the substrate 12 and along an edge 19 that is transverse to the under side 18. In order to form the anchoring formation/joint between the plated areas, solder material is deposited over the plated area 32 and the components 12, 30 are brought into contact, whereafter a solder reflow operation is performed. The resultant anchor joint 42 is shown in FIG. 6B of the drawings, and referred to as a wraparound solder joint since the joint itself wraps around the under side 18 and the edge 19 of the substrate board 12. To form the wraparound solder joint 42, a sufficient amount of solder material has to be deposited on the plated area 32. Accordingly, the stencil 36 that is used to print the solder material onto the plated area 32 has apertures 38 that are larger than the dimensions of the actual plated area 32, as can be seen in FIG. 7 of the drawings.

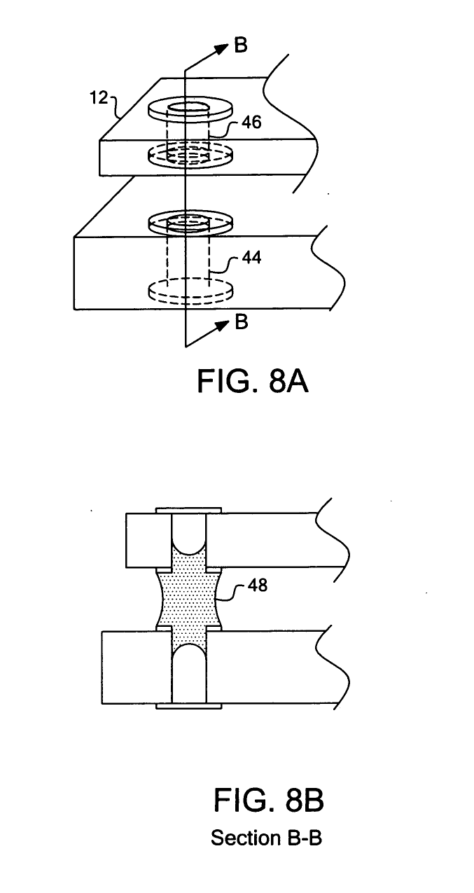

In order to improve the strength of the resultant in anchoring formation/joint, in some embodiments, the solder material may actually extend into the substrate 12. For example in the embodiment shown in FIG. 8 of the drawings, circular, or disc-shaped plated areas are formed on a substrate 30, and a motherboard 30, respectively. Next, plated thru-holes (vias) 44, 46 are formed, for example by drilling, into the substrate 12, and the motherboard 30, respectively. The presence of the plated thru-holes 44, 46, allow the solder material that is deposited during the flip-chip assembly process to move partially into the plated thru-holes 44, 46 so that the resultant anchoring formation/joint 48 formed after the solder reflow operation extends partly into the substrate board 12 and the motherboard 30, as can be seen in FIG. 8B of the drawings.

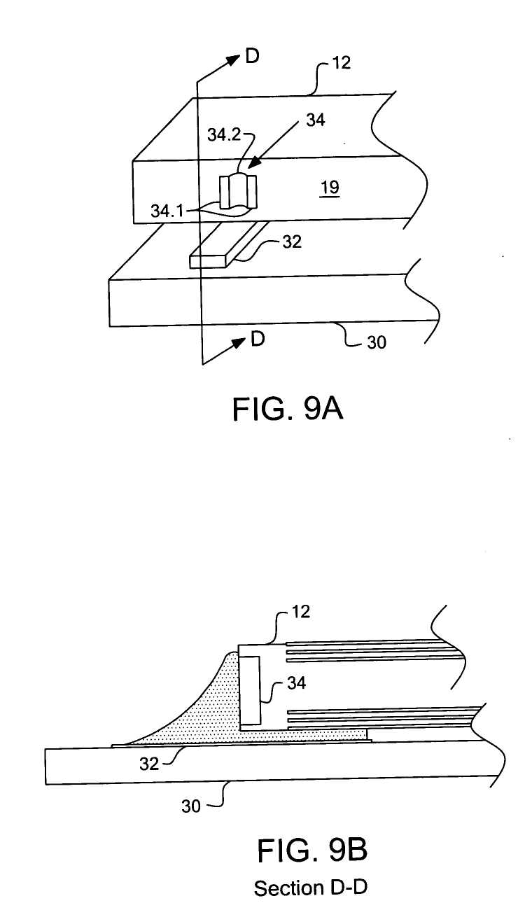

In one embodiment, a wraparound solder joint may be formed, as is shown in FIG. 9A of the drawings, with a difference that part of the material of the wraparound solder joint that is adjacent to the side edge 19 of the substrate board 12, actually extends into the substrate board 12 itself. For this embodiment, the substrate board 12 includes a plated area 34 along its side edge 19 with the characteristic that the plated area 34 extends, at least partly into the substrate board 12. For example, referring the FIG. 9 of the drawings, the plated area 34 includes two end sections 34.1 that are flush with the side edge 19 of the substrate board 12, and a middle section 34.2 which is channel-shaped and extends into the side 19 of the substrate board 12. The resultant wraparound solder joint for this configuration of the plated areas 34, 32 is shown in FIG. 9B of the drawings, and as will be seen includes solder material that extends into the substrate board 12.

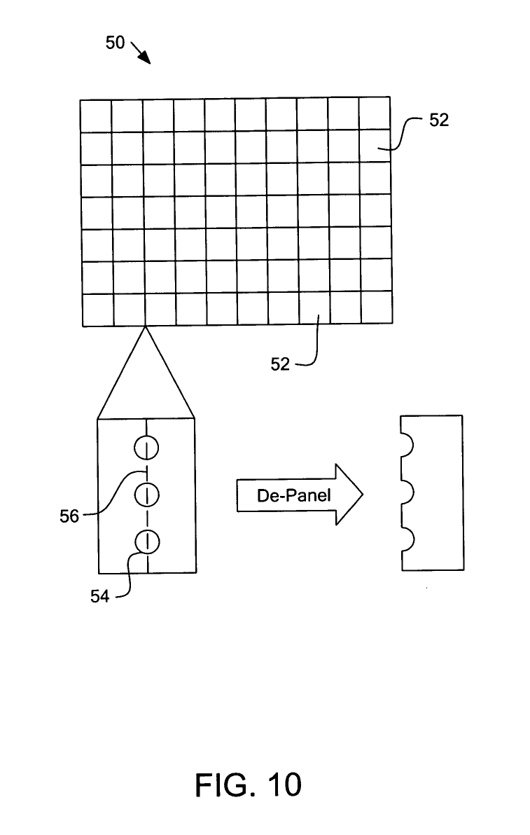

In order to form the plated area 34.2 shown in FIG. 9A of the drawings, a de-panel process used to separate or de-panel the substrate board 12 from other substrate boards 12 is modified as follows. Referring to FIG. 10, a component panel 50 is fabricated in conventional fashion, to include a plurality of components substrates 52. Scribe lines 54 are formed between the component substrates 52 in order to facilitate separation of the component substrates 52 from the component panel 50. Before the actual separation, in one embodiment of the invention, vias 54 are drilled into the component panel 50 to coincide with the scribe lines 56. For example, in one embodiment, the vias 54 are circular in shape and each vias 54 straddles a single scribe line 56 so that when the components are separated, each half of a via 50 that straddled a scribe line 56 forms a channel-shape. Before separation, the vias 54 are plated with a solder-wettable material using a conventional plated process.

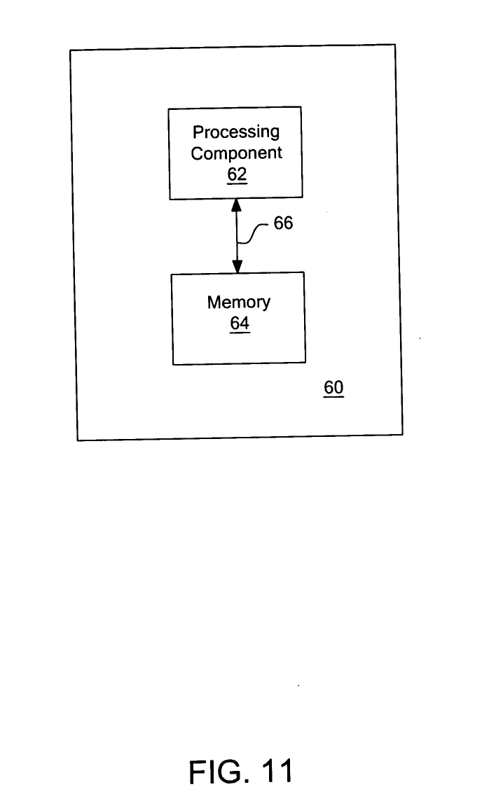

FIG. 11 shows a system 60 in accordance with one embodiment of the present invention, the system includes a processing component 62 which is coupled to a memory 64, via communications interface, such as a bus 66. The processing component includes a substrate package which includes a substrate board 12 and semiconductor die 16, and a carrier board 30 which is coupled to the substrate package, as described above.

Although the present invention has been described with reference to specific exemplary embodiments, it will be evident that the various modification and changes can be made to these embodiments without departing from the broader spirit of the invention as set forth in the claims. Accordingly, the specification and drawings are to be regarded in an illustrative sense rather than in a restrictive sense.

What is claimed is:

1. A method, comprising:
forming a plurality of electromechanical formations to electromechanically couple a first printed circuit board to a second printed circuit board, wherein each electromechanical formation is of a first size; and
forming at least one anchoring formation to anchor the first printed circuit board to the second printed circuit board, each anchoring formation being formed at a selected anchor point, and being of a second size which is greater than the first size.

2. The method of claim 1, wherein the first printed circuit board comprises a substrate board electromechanically coupled to a semiconductor die to form a substrate package.

3. The method of claim 2, wherein the second printed circuit board comprises a motherboard for the substrate package.

4. The method of claim 1, wherein forming the anchoring formation comprises forming a solder joint between complementary plated areas of the first and second printed circuit boards.

5. The method of claim 1, wherein forming the anchoring formation comprises forming complementary plated through holes in the first and second printed circuit boards; depositing solder material adjacent the through hole of the second printed circuit board; and reflowing the solder material to form a solder joint which extends partially into the complementary plated through holes.

6. The method of claim 1, wherein forming the anchoring formation comprises forming a wraparound solder joint that extends partially along an underside of the first printed circuit board which is in a face-to-face relationship with an upper side of the second printed circuit board, and partially along an edge of the first printed circuit board which is transverse to the underside.

7. The method of claim 6, further comprising first plating areas of the underside and edge of the first printed circuit, and the upper side of the second printed circuit board with a solder wettable material.

8. The method of claim 1, wherein forming the anchoring formation comprises forming a via which is exposed along an edge of the first printed circuit board extending between an upper side and an underside of the first printed circuit board; and forming a wraparound solder joint that extends partially along the underside of the first printed circuit board and partially along the exposed via.

9. The method of claim 1, wherein the selected anchor point comprises a corner of the first printed circuit board.

10. The method of claim 1, wherein the selected anchor point comprises peripheral areas of an underside of the first printed circuit board that is in a face-to-face relationship with the second printed circuit board.

11. An apparatus, comprising:
a substrate package comprising a substrate board and a semiconductor die electromechanically coupled thereto; and
a carrier board electromechanically coupled to the substrate package through a plurality of electromechanical formations formed between an underside of the substrate board and an upper side of the carrier board, the electromechanical formations being of a first size, the carrier board being anchored to the substrate board through at least one anchoring formation formed at a selected anchor point, the at least one anchoring formation being of a second size which is greater than the first size.

12. The apparatus of claim 11, wherein the anchoring formation comprises a solder joint formed between complementary plated areas of the carrier board, and the substrate board, respectively.

13. The apparatus of claim 11, wherein the anchoring formation comprises a solder joint which includes solder material that extends into complementary plated through holes formed in the substrate, and carrier board, respectively.

14. The apparatus of claim 11, wherein the anchoring formation comprises a wraparound solder joint comprising solder material that extends partially along an underside of the substrate board and an upper side of the carrier board, and partially along an edge of the substrate board which is transverse to the underside of the substrate board.

15. The apparatus of claim 11, wherein the anchoring formation comprises a wraparound solder joint comprising solder material that extends partially along an underside of the substrate board and partially along and via which is exposed along an edge of the substrate board.

16. The apparatus of claim 11, wherein the selected anchor point comprises a corner of the substrate board.

17. The apparatus of claim 11, wherein the selected anchor point comprises peripheral areas of an underside of the substrate board that is in a face-to-face relationship with an upper side of the carrier board.

18. A system, comprising:
a processing component comprising
a substrate package, including a substrate board and a semiconductor die electromechanically coupled thereto; and
a carrier board electromechanically coupled to the substrate package through a plurality of electromechanical formations formed between an underside of the substrate board and an upper side of the carrier board, the electromechanical formations being of a first size, the carrier board being anchored to the substrate board through at least one anchoring formation formed at a selected anchor point, and being of a second size which is greater than the first size; and
a memory coupled to the processing component via a bus.

19. The system of claim 18, wherein the anchoring formation comprises solder joint which extends partially into complementary plated through holes formed in the first and second printed circuit boards, respectively.

20. The system of claim 18, wherein the anchoring formation comprises a wraparound solder joint that extends partially along an underside of the first printed circuit board which is in a face-to-face relationship with an upper side of the second printed circuit board, and partially along an edge of the first printed circuit board which is transverse to the underside.

21. The system of claim 18, wherein the anchoring formation comprises a wraparound solder joint that extends partially along the underside of the first printed circuit board and partially along a via which is exposed along an edge of the first printed circuit board extending between an upper side and an underside of the first printed circuit board.

22. The system of claim 18, wherein the selected anchor point comprises a corner of the first printed circuit board.
